(19) United States
(12) Patent Application Publication
(10) Pub. No.: US 2014/0353696 A1
(43) Pub. Date: Dec. 4, 2014

(54) Solid State Lighting Device

(71) Applicant: Toshiba Lighting & Technology Corporation, Yokosuka-shi (JP)

(72) Inventors: Junichi Kinoshita, Yokosuka-shi (JP); Yoshihisa Ikeda, Yokosuka-shi (JP)

(73) Assignee: Toshiba Lighting & Technology Corporation, Yokosuka-shi (JP)

(21) Appl. No.: 14/144,625

(22) Filed: Dec. 31, 2013

(30) Foreign Application Priority Data
May 31, 2013 (JP) 2013-116183

(51) Int. Cl. H01L 33/50

(52) U.S. Cl. CPC H01L 33/50
USPC 257/89

(57) ABSTRACT

A solid state lighting device includes a first solid state light-emitting element configured to emit first light having a first light emission spectrum having width smaller than 5 nm in a visible light wavelength region; a second solid state light-emitting element configured to emit second light having a second light emission spectrum having width smaller than 5 nm and a peak wavelength larger than a peak wavelength of the first light by 5 nm or more in the visible light wavelength region, and a plurality of first light-emitting elements for wavelength complement configured to respectively emit lights having light emission spectra having width smaller than 5 nm. A third light emission spectrum of third light, which is a set of the lights from the plurality of first light-emitting elements for complement, complements a region between the first light emission spectrum and the second light emission spectrum.

### CROSS-REFERENCE TO RELATED APPLICATIONS

This application is based upon and claims the benefit of priority from Japanese Patent Application No. 2013-116183, filed on May 31, 2013; the entire contents of which are incorporated herein by reference.

### FIELD

Embodiments described herein relate generally to a solid state lighting device.

### BACKGROUND

As a light source of an SSL (Solid State Lighting) device including a solid state light-emitting element, an LED (Light Emitting Diode) is the mainstream.

For example, if a white light-emitting section including a phosphor is provided to cover an LED (Light Emitting Diode) chip to obtain white light, a substrate for thermal radiation and power supply for the LED chip is necessary. On the other hand, if the white light-emitting section is configured by only an optical system, heat generation is small and the weight of the white light-emitting section is reduced. Therefore, it is possible to improve a degree of freedom of design of a lighting device.

Therefore, for example, a structure only has to be adopted to efficiently couple laser light emitted from a semiconductor laser (LD: Laser Diode), which has a wavelength range of a blue-violet to blue color, to a light guide body or the like and irradiate the laser light on a wavelength conversion layer of a phosphor or the like separated from a solid state light-emitting element to obtain white light.

However, if blue LD light and yellow wavelength-converted light from a YAG (Yttrium Aluminum Garnet) phosphor are mixed, a light emission spectrum component in a red region is small. Therefore, it is difficult to realize a white lamp having a low color temperature. If the intensity of yellow light is increased, although a yellow spectral region increases, a red spectral region does not relatively increase. Therefore, a color rendering property falls and, for example, an average color rendering index Ra falls.

The blue LD light usually has longitudinal multi-modes. The width of a light emission spectrum represented as an envelope of a set of longitudinal multi-modes is 2 to 3 nm or the like and is narrower than 10 to 20 nm, which is a full width at half maximum of an LED. Even if a light emission spectral width of the yellow light by the YAG phosphor is large, since the light emission spectral width of the blue LD light is narrow, a missing region of a continuous spectrum widens and the color rendering property is deteriorated.

### DESCRIPTION OF THE DRAWINGS

FIG. 1 is a schematic perspective view of a solid state lighting device according to a first embodiment;

FIG. 2A is a schematic diagram of a light emission spectrum of the solid state lighting device in the first embodiment;

FIG. 2B is a schematic diagram of a light emission spectrum of a solid state light-emitting element;

FIG. 3 is a schematic diagram of a light emission spectrum of a modification of the solid state lighting device according to the first embodiment;

FIG. 4 is a schematic diagram of a light emission spectrum of a solid state lighting device according to a first comparative example;

FIG. 5 is a schematic diagram of a light emission spectrum of a solid state lighting device according to a second comparative example;

FIG. 6 is a chromaticity diagram for explaining color reproducibility in a display device;

FIG. 7 is a schematic diagram of a light emission spectrum of a solid state lighting device according to a second embodiment;

FIG. 8 is a schematic perspective view of a solid state lighting device according to a third embodiment;

FIG. 9 is a schematic diagram of a light emission spectrum of the solid state lighting device according to the third embodiment;

FIGS. 10A to 10D are schematic diagrams for explaining a method for manufacturing a second light-emitting element for wavelength complement, wherein FIG. 10A is a schematic sectional view of a chip, FIG. 10B is a schematic sectional view of a state in which the chip is bonded to a reflection plate, FIG. 10C is a schematic sectional view after selective etching, and FIG. 10D is a schematic sectional view in which a wavelength converting section is provided;

FIG. 11 is a schematic perspective view of a solid state lighting device according to a fourth embodiment;

FIG. 12 is a schematic diagram of a light emission spectrum of the solid state lighting device according to the fourth embodiment; and

FIG. 13 is a schematic diagram of a light emission spectrum of a solid state lighting device according to a fifth embodiment.

### DETAILED DESCRIPTION

In general, according to an embodiment, there is provided a solid state lighting device including: a first solid state light-emitting element configured to emit first light having a first light emission spectrum having width smaller than 5 nm in a visible light wavelength region; a second solid state light-emitting element configured to emit second light having a second light emission spectrum having width smaller than 5 nm and a peak wavelength larger than a peak wavelength of the first light by 5 nm or more in the visible light wavelength region; and a plurality of first light-emitting elements for wavelength complement configured to respectively emit lights having light emission spectra having width smaller than 5 nm. A third light includes a set of the lights from the plurality of first light-emitting elements for complement. A third light emission spectrum of the third light complements a region between the first light emission spectrum and the second light emission spectrum.

According to a first aspect, there is provided a solid state lighting device including: a first solid state light-emitting element configured to emit first light having a first light emission spectrum having width smaller than 5 nm in a visible light wavelength region; a second solid state light-emitting element configured to emit second light having a second light emission spectrum having width smaller than 5 nm and a peak wavelength larger than a peak wavelength of the first light by 5 nm or more in the visible light wavelength region; and a plurality of first light-emitting elements for wavelength complement configured to respectively emit lights having light emission spectra having width smaller than 5 nm. A third light emission spectrum of third light, which is a set of the lights from the plurality of first light-emitting elements for complement, complements a region between the first light emission spectrum and the second light emission spectrum.

The solid state lighting device includes the first and second solid state light-emitting elements and the solid state light-emitting elements for wavelength complement. Therefore, it is possible to complement a missing region and a bottom region of a light emission spectrum that occur between the first light emission spectrum of the first solid state light-emitting element and the second light emission spectrum of the second solid state light-emitting element. As a result, it is possible to improve a color rendering property.

According to a second aspect, in the solid state lighting device in the first aspect, the third light includes at least a pair of lights having a peak wavelength interval equal to or smaller than 5 nm.

According to the aspect, it is possible to more surely improve the color rendering properties.

According to a third aspect, in the solid state lighting device in any of the first and second aspects, the first and second solid state light-emitting elements and the plurality of first light-emitting elements for wavelength complement are semiconductor lasers.

According to the aspect, a region between the light emission spectra of the first and second semiconductor lasers is complemented by the light emission spectra of the plurality of semiconductor lasers. Therefore, it is possible to improve the color rendering property. p According to a fourth aspect, the solid state lighting device in any of the first to third aspects further includes a light guide section configured to guide the first light, the second light, and the third light; and a lamp section including a first wavelength converting section configured to absorb at least the first light guided by the light guide section, emit first wavelength-converted light having a peak wavelength larger than the peak wavelength of the first light and smaller than the peak wavelength of the second light, and scatter the first, second, and third lights. Scattered lights of the first, second, and third lights and the first wavelength-converted light are emitted from the lamp section.

According to the aspect, it is possible to separate the solid state light-emitting elements and the lamp section and improve a thermal radiation property. Further, it is possible to reduce the lamp section in size and weight.

According to a fifth aspect, in the solid state lighting device in the fourth aspect, the third light emission spectrum substantially coincides with a shape obtained by multiplying, with a color matching function, a value obtained by subtracting the light emission spectrum of the first wavelength-converted light from a blackbody radiation spectrum at a requested color temperature and complements a region between the first light emission spectrum and the second light emission spectrum.

According to the aspect, it is possible to easily obtain a continuous light emission spectrum for wavelength complement. Therefore, it is possible to improve the color rendering property.

According to a sixth aspect, the solid state lighting device in the first or second aspect further includes a third solid state light-emitting element configured to emit fourth light having width of a light emission spectrum smaller than 5 nm and having a peak wavelength larger than the peak wavelength of the first light by 5 nm or more and smaller than the peak wavelength of the second light by 5 nm or more in the visible light wavelength region, the third solid state light-emitting element including a semiconductor laser.

According to the aspect, it is possible to further reduce heat generation of the lamp section.

According to a seventh aspect, in the solid state lighting device in the sixth aspect, the third light emission spectrum substantially coincides with a shape obtained by multiplying a blackbody radiation spectrum at a requested color temperature with a color matching function.

According to the aspect, it is possible to easily obtain a light emission spectrum for wavelength complement. Therefore, it is possible to improve the color rendering property.

According to an eighth aspect, there is provided a solid state lighting device including: a first solid state light-emitting element configured to emit first light having a first light emission spectrum having width smaller than 5 nm in a visible light wavelength region; a second solid state light-emitting element configured to emit second light having a second light emission spectrum having width smaller than 5 nm and a peak wavelength larger than a peak wavelength of the first light by 5 nm or more in the visible light wavelength region; and a second light-emitting element for wavelength complement configured to emit third light having a continuous third light emission spectrum having a full width at half maximum equal to or larger than 5 nm in the visible light wavelength region and for complementing a region between the first light emission spectrum and the second light emission spectrum, the second light-emitting element for wavelength complement including a second wavelength converting section configured to absorb the first light and emit second wavelength-converted light having a peak wavelength larger than the peak wavelength of the first light or a third wavelength converting section configured to set at least one of the first light and the second light as excitation light and emit third wavelength-converted light having a peak wavelength larger than a peak wavelength of the excitation light.

The solid state lighting device includes the first and second solid state light-emitting elements and the solid state light-emitting element for wavelength complement including the wavelength converting section. Therefore, it is possible to complement a missing region and a bottom region of a light emission spectrum that occur between the first light emission spectrum of the first solid state light-emitting element and the second light emission spectrum of the second solid state light-emitting element. As a result, it is possible to improve the color rendering property.

According to a ninth aspect, in the solid state lighting device in the eighth aspect, the second wavelength converting section includes a phosphor.

According to the aspect, it is possible to easily perform complement of a light emission spectrum using the phosphor. As a result, it is possible to improve the color rendering property.

According to a tenth aspect, in the solid state lighting device in the eighth aspect, the third wavelength converting section includes a semiconductor laminated body configured to perform photoluminescence light emission.

According to the aspect, it is possible to easily perform complement of a light emission spectrum using the photoluminescence light emission. As a result, it is possible to improve the color rendering property.

According to an eleventh aspect, in the solid state lighting device in the tenth aspect, the semiconductor laminated body includes an active layer and layers on both sides that sandwich the active layer, the semiconductor laminated body being an undoped layer.

According to the aspect, it is possible to easily perform complement of a light emission spectrum using the photoluminescence light emission. As a result, it is possible to improve the color rendering property.

According to a twelfth aspect, the solid state lighting device in any of the eighth to eleventh aspects further includes:

a light guide section configured to guide the first and second lights; and a lamp section including a first wavelength converting section configured to absorb the first light guided by the light guide section, emit first wavelength-converted light having a peak wavelength larger than the peak wavelength of the first light and smaller than the peak wavelength of the second light, and scatter the first and second lights. Scattered lights of the first and second lights, the first wavelength-converted light, and the third light are emitted from the lamp section.

According to the aspect, it is possible to separate the solid state light-emitting elements and the lamp section and improve a thermal radiation property. Further, it is possible to reduce the lamp section in size and weight.

According to a thirteenth aspect, in the solid state lighting device in the twelfth aspect, the second light-emitting element for wavelength complement is provided on a supporting section, the third light emission spectrum substantially coincides with a shape obtained by multiplying, with a color matching function, a value obtained by subtracting the light emission spectrum of the first wavelength-converted light from a blackbody radiation spectrum at a requested color temperature, and the scattered lights of the first and second lights, the first wavelength-converted light, and the third light are mixed and emitted from the lamp section.

According to the aspect, it is possible to easily obtain a light emission spectrum for wavelength complement. Therefore, it is possible to improve the color rendering property.

According to a fourteenth aspect, the solid state lighting device in any of the eighth to eleventh aspects further includes a third solid state light-emitting element configured to emit fourth light having width of a light emission spectrum smaller than 5 nm and having a peak wavelength larger than the peak wavelength of the first light by 5 nm or more and smaller than the peak wavelength of the second light by 5 nm or more in the visible light wavelength region.

According to the aspect, it is possible to further reduce heat generation of the lamp section.

According to a fifteenth aspect, in the solid state lighting device in the fourteenth aspect, the third light emission spectrum of the second light-emitting element for wavelength complement substantially coincides with a shape obtained by multiplying a blackbody radiation spectrum at a requested color temperature with a color matching function and complements a region between the first light emission spectrum and the second light emission spectrum.

According to the aspect, it is possible to easily obtain a light emission spectrum of a light-emitting element for wavelength complement. Therefore, it is possible to improve the color rendering property.

According to a sixteenth aspect, in the solid state lighting device in any of the first to fifteenth aspects, the peak wavelength of the first light is equal to or larger than 420 nm and equal to or smaller than 480 nm, the peak wavelength of the second light is equal to or larger than 620 nm and equal to or smaller than 650 nm, and the peak wavelength of the third light is equal to or larger than 460 nm and equal to or smaller than 630 nm.

According to the aspect, it is possible to easily obtain white light rich in the color rendering property.

Embodiment are explained below with reference to the drawings. Note that, in the drawings, the same components are denoted by the same reference numerals and signs and detailed explanation of the components is omitted as appropriate.

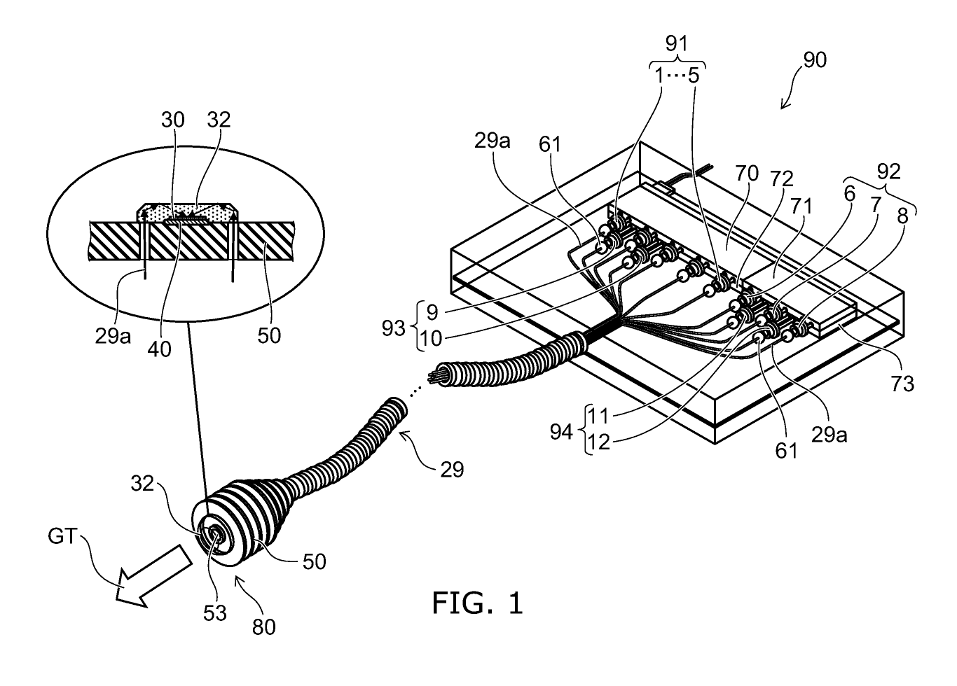

FIG. 1 is a schematic perspective view of a solid state lighting device according to a first embodiment. The solid state lighting device includes a light source for illumination 90, a light guide section 29, and a lamp section 80. The light source for illumination (a light engine) 90 includes a first solid state light-emitting element 91, a second solid state light-emitting element 92, and first light-emitting elements for wavelength complement 93 and 94.

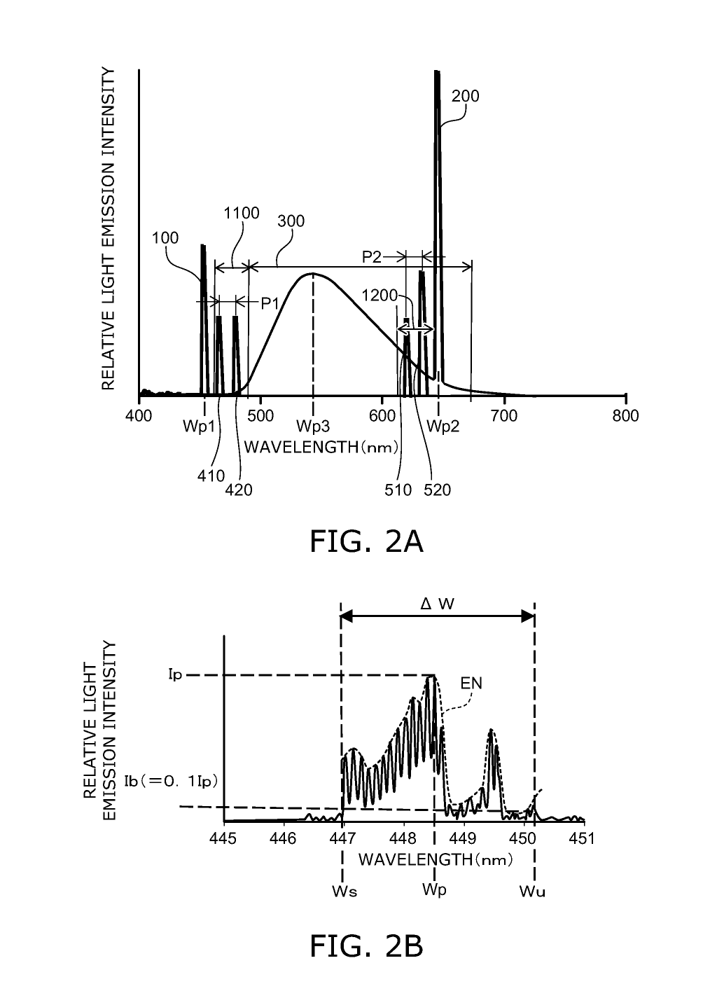

FIG. 2A is a schematic diagram of a light emission spectrum of the solid state lighting device in the first embodiment. FIG. 2B is a schematic diagram of a light emission spectrum of an LD.

The light emission spectrum is represented with relative light emission intensity plotted on the ordinate and a wavelength (nm) plotted on the abscissa. The first solid state light-emitting element 91 emits first light having the width of a light emission spectrum 100 smaller than 5 nm in a visible light wavelength region. The visible light wavelength region refers to a wavelength region equal to or larger than 360 nm and equal to or smaller than 830 nm. The second solid state light-emitting element 92 emits second light having the width of a light emission spectrum 200 smaller than 5 nm and having a peak wavelength Wp2 larger than a peak wavelength Wp1 of the first light by 5 nm or more in the visible light wavelength region. Note that a wavelength at which the relative light emission intensity has a peak value is referred to as peak wavelength.

The first light-emitting element for wavelength complement 93 includes, for example, a plurality of solid state light-emitting elements and emits third light. The first light-emitting element for wavelength complement 94 includes, for example, a plurality of solid state light-emitting elements and emits third light.

In FIG. 1, the light guide section 29 includes a transparent medium or a hollow light guide body and guides first light, second light, and third light to the lamp section 80. The light guide section 29 can be, for example, optical fibers 29a including cores, which are transparent media, and clads for covering the cores and made of quartz. If condensing lenses 61 or the like are provided between the first and second solid state light-emitting elements 91 and 92 and the first light-emitting elements for wavelength complement 93 and 94 and the optical fibers 29a, it is easy to improve efficiency of incidence on the optical fibers 29a.

The lamp section 80 includes, for example, a supporting body 50, a first wavelength converting section 30 provided on the supporting body 50, and a direction-converting optical section 32. The first wavelength converting section 30 includes a YAG phosphor or the like, absorbs the first light, and emits first wavelength-converted light having a peak wavelength Wp3 larger than the peak wavelength Wp1 of the first light and smaller than the peak wavelength Wp2 of the second light and having a wide light emission spectrum 300. The first wavelength-converted light can be green light or the like. If the supporting body 50 is made of metal, ceramic having high thermal conductivity, or the like, the supporting body 50 can be a heat sink having high heat dissipation. The lamp section 80 only has to be a component including the first wavelength converting section 30 on which at least the first light guided by the light guide section 29 is irradiated. The lamp section 80 is not specifically limited to a light-emitting structure.

The first to third lights emitted from the light guide section 29 are led into the direction-converting optical section 32. The direction-converting optical section 32 changes traveling directions of the first to third lights and scatters the first and second lights. The direction-converting optical section 70 can be made of glass, translucent resin, or the like.

In the first embodiment, the first solid state light-emitting element 91 can be blue LDs 1 to 5 or the like. The width of the light emission spectrum 100 of the first solid state light-emitting element 91 is smaller than 5 nm. The first solid state light-emitting element 91 emits the first light having the peak wavelength Wp1. The second solid state light-emitting element 92 can be red LDs 6 to 8 or the like. The width of a light emission spectrum of the second solid state light-emitting element 92 is smaller than 5 nm. The second solid state light-emitting element 92 emits the second light having the peak wavelength Wp2. The first wavelength converting section 30 emits the first wavelength-converted light, which is green light or the like, having the peak wavelength Wp3. That is, the first light, the second light, and the first wavelength-converted light mainly control the chromaticity and the color temperature of illumination light GT. Therefore, the blue LDs 1 to 5 and the red LDs 6 to 8 emit lights having a main light emission spectrum.

As shown in FIG. 2B, a light emission spectrum of an LD used in a solid state lighting device often has longitudinal multi-modes. That is, vertical multi-modes having slightly different wavelengths occur in the length direction of a resonator. In this specification, the light emission spectrum of the LD is treated as an envelope EN of a set of the longitudinal multi-modes. That is, light emission spectra 100, 200, 410, 420, 510, and 520 shown in FIG. 2A are respectively vertical multi-modes.

In this specification, “a lower limit wavelength Ws of a light emission spectrum” is defined as a wavelength at which relative light emission intensity falls to 10% (Ib) of relative light emission intensity Ip at the peak wavelength Wp (Ws<Wp). “An upper limit wavelength Wu of a light emission spectrum” is defined as a wavelength at which relative light emission intensity falls to 10% (Ib) of the relative light emission intensity Ip at the peak wavelength Wp (Wp<Wu).

In this specification, “width” of a light emission spectrum is defined as a subtraction value of the upper limit wavelength Wu and the lower limit wavelength Ws (Wu−Ws=ΔW).

In the case of the first light-emitting elements for wavelength complement 93 and 94 including a plurality of LDs, intervals P1 and P2 between adjacent two peak wavelengths are set to be equal to or smaller than 5 nm. The widths of the light emission spectra 410, 420, 510, and 520 are set to be smaller than 5 nm. A region where the light emission spectra are missing can be set to be smaller than 5 nm. Therefore, it is possible to improve a color rendering property. In this way, the LDs for wavelength complement mainly emit lights having light emission spectra for wavelength complement for improving the color rendering property.

The wavelength converting section absorbs excitation light and emits wavelength-converted light having a light emission spectrum having a wavelength larger than the wavelength of the excitation light. As the wavelength converting section, a single phosphor or a mixture of at least one or more kinds of phosphors selected out of nitride phosphors such as (Ca,Sr)₂Si₅N₈:Eu and (Ca,Sr)AlSiN₃:Eu, oxynitride phosphors such as Cax(Si,Al)₁₂(O,N)₁₆:Eu, (Si,Al)₆(O,N)₈:Eu, BaSi₂O₂N₂:EU, and BaSi₂O₂N₂:Eu, oxide phosphors such as Lu₃Al₅O₁₂:Ce, (Y,Gd)₃(Al,Ga)₅O₁₂:Ce, (Sr,Ba)₂SiO₄: Eu, Ca₃Sc₂Si₃O₁₂:Ce, and Sr₄Al₁₄O₂₅:Eu, and sulfide phosphors such as (Ca,Sr)S:Eu, CaGa₂S₄:Eu, and ZnS:Cu,Al can be used.

For example, when blue LD light is irradiated, the first wavelength converting section 30 including a green phosphor emits green light. As a result, the lamp section 80 emits white light or the like as the illumination light GT. Note that, as shown in FIG. 1, the first wavelength converting section 30 can be formed on a reflection plate 40. The reflection plate 40 can be mounted on the surface of the supporting body 50.

Most of heat generation that occurs in the lamp section 80 is caused by a conversion loss of the first wavelength converting section 30. Therefore, the size of the supporting body 50 can be set to be smaller than the size of an LED in which a phosphor and a light source are integrated. The lamp section 80 can be reduced in size and weight and reduced in heat generation. That is, it is possible to realize a large-light amount and high-luminance lamp configured by an optical component. Further, a degree of freedom of design is greatly improved.

The light source for illumination 90 can further include a first driving circuit 70, a second driving circuit 71, a third driving circuit 72, and a fourth driving circuit 73. The first driving circuit 70 drives, for example, the first solid state light-emitting element 91 including the blue LDs 1 to 5. The second driving circuit 71 drives, for example, the second solid state light-emitting element 92 including the red LDs 6 to 8. The third driving circuit 72 drives, for example, the first light-emitting element for wavelength complement 93 including two blue LDs 9 and 10. The fourth driving circuit 73 drives, for example, the first light-emitting element for wavelength complement 94 including two red LDs 11 and 12. Note that the numbers of the LDs included in the first and second solid state light-emitting elements 91 and 92 are not limited to the above. The first light-emitting elements for wavelength complement 93 and 94 include the plurality of LDs. However, the number of the LDs is not limited to the above.

The peak wavelength Wp1 of the first light of the first solid state light-emitting element 91 is set to be, for example, equal to or larger than 420 nm and equal to or smaller than 480 nm. The peak wavelengths of the blue LDs 1 to 5 configuring the first solid state light-emitting element 91 are set substantially the same. The peak wavelength Wp2 of the second light of the second solid state light-emitting element 92 is set to, for example, 620 to 650 nm. The peak wavelengths of the red LDs 6 to 8 configuring the second solid state light-emitting element 92 are set substantially the same. Since the peak wavelengths are set substantially the same, it is easy to increase an output of the solid state lighting device.

The light emission spectra of the first blue LDs for wavelength complement LD9 and LD10 are respectively 410 and 420 shown in FIG. 2A. The peak wavelengths of the light emission spectra of the first blue LDs for wavelength complement LD9 and LD10 are set to be larger than the peak wavelengths of the blue LDs 1 to 5 configuring the first solid state light-emitting element 91. The light emission spectra of the first red LDs for wavelength complement LDs 11 and 12 are respectively 510 and 520 shown in FIG. 2A. The peak wavelengths of the light emission spectra of the first red LDs for wavelength complement LDs 11 and 12 are set to be smaller than the peak wavelengths of the red LDs 6 to 8 configuring the second solid light-emitting elements 92. Consequently, it is possible to set the visual sensitivity of the first light-emitting elements for wavelength complement higher than the visual sensitivity of the first and second solid-state light-emitting elements 91 and 92 and improve the color rendering property with a lower optical output.

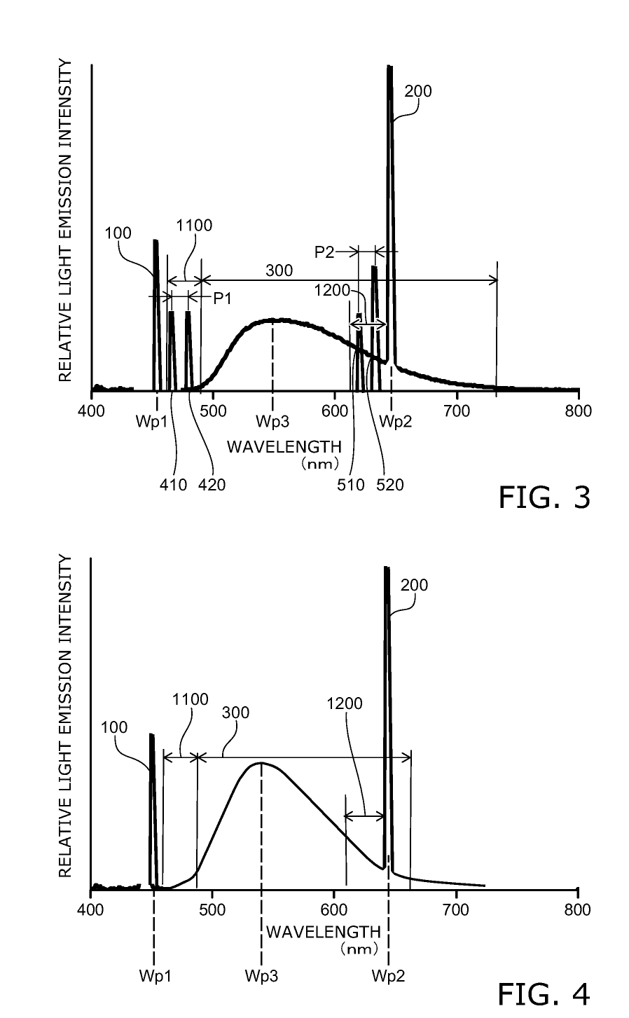

FIG. 3 is a schematic diagram of a light emission spectrum of a modification of the solid state lighting device according to the first embodiment.

The first wavelength converting section 30 can also be a yellow phosphor. If the yellow phosphor is used, it is possible to expand the light emission spectrum to a longer wavelength range.

FIG. 4 is a schematic diagram of a light emission spectrum of a solid state lighting device according to a first comparative example.

The solid state lighting device in the first comparative example includes a first solid state light-emitting element configured to emit light having a peak wavelength in a range of 420 to 480 nm and including a blue LD or the like and a second solid state light-emitting element configured to emit light having a peak wavelength in a range of 620 to 650 nm and including a red LD or the like. However, the solid state lighting device does not include a light-emitting element for wavelength complement. The solid state lighting device includes a wavelength converting section and emits green wavelength-converted light.

A spectrum missing region 1100 is formed between the light emission spectrum 100 of blue LD light and the light emission spectrum 300 of wavelength-converted light, which is green light. A bottom region 1200 having low light emission spectrum intensity is formed between the peak wavelength Wp3 of the wavelength-converted light and the light emission spectrum 200 of red LD light. If the solid state lighting device is used for a display, a color gamut generated by mixed light of these lights suffices. However, to use the solid state lighting device for illumination light, the color rendering property is not considered to be sufficient.

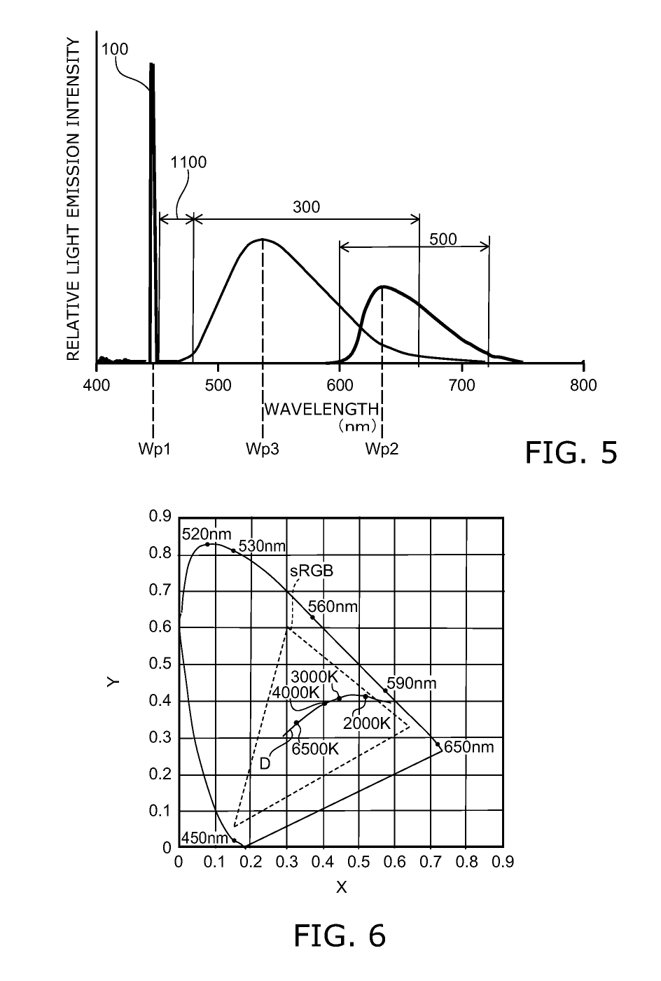

FIG. 5 is a schematic diagram of a light emission spectrum of a solid state lighting device according to a second comparative example

In the second comparative example, a red phosphor is added to a green phosphor to increase the intensity of a light emission spectrum 500 of red wavelength-converted light. However, if the red phosphor is excited by the blue LD light, the efficiency of wavelength conversion falls because of a Stokes shift in which light having a wavelength larger than the wavelength of the blue LD light is emitted. If it is attempted to reduce a color temperature, in particular, an amount of the red phosphor increases. Therefore, overall efficiency markedly falls and heat generation increases. Further, the efficiency sometimes further falls because the light emission spectrum 500 of the red phosphor excessively expands to an infrared region. That is, the efficiency falls if only the wavelength-converted light by the phosphor is used as red light.

FIG. 6 is a chromaticity diagram for explaining color reproducibility in a display device.

As a standard of a range in which a color can be reproduced, i.e., a so-called color gamut, there are, for example, the sRGB standard set by the International Electromechanical Commission and the NTSC (National Television System Committee) standard set by the National Television Standard Committee. In the figure, the sRGB standard is represented by a broken line. In the first embodiment, a triangular color gamut corresponding to the sRGB standard can be provided by the first solid state light-emitting element 91 including the blue LD or the like, the second sold state light-emitting element 92 including the red LD or the like, and the wavelength converting section including the green phosphor or the like. That is, since pure three primary colors having narrow light emission spectra are located at edges of the chromaticity diagram, a color gamut is wider.

On the other hand, a color rendering property by illumination is different from the color gamut in the display. The color rendering property is evaluated according to how reflected light of an illuminated object is close to reflected light obtained when the object is irradiated by the sunlight having a continuous spectrum. Even if a color gamut determined by the triangle of the pure three primary colors (spectrum narrow line width) is wide, if there is a missing region of a light emission spectrum among the three primary colors, reflected light having rich colors like natural light having a continuous spectrum cannot be reproduced. The color rendering property is evaluated using the average color rendering index Ra or the like. This measurement is normally performed at an interval of 5 nm taking into account human color recognition accuracy. Therefore, when a missing region equal to or larger than 5 nm is present in a light emission spectrum, the color rendering property is deteriorated. That is, even if a missing region and a bottom region of a light emission spectrum are present, the deterioration in the color rendering property can be surely suppressed if an interval between the missing region and the bottom region is smaller than 5 nm. However, even if the interval is larger than 5 nm, the deterioration in the color rendering property can be suppressed to some degree.

The color rendering property is a difference from reflection by natural light illumination at a certain color temperature. However, a color temperature is determined by the balance of the three primary colors and a color gamut in a broadcast is determined by the three primary colors. For example, an illumination spectrum component outside the color gamut has little influence on illumination in the site of a broadcasting station.

The visual sensitivity has a peak value at a wavelength of about 555 nm. Therefore, the first light emission spectrum 100 of the first solid state light-emitting element 91 and the second light emission spectrum 200 of the second solid state light-emitting element 92 are regions where the visual sensitivity is low. A wavelength region on the outer side of the region has lower visual sensitivity. Therefore, from the viewpoint of keeping the efficiency high, the wavelength region is desirably absent. This is a reason why a complementary spectrum is set only on the inner side of the first light emission spectrum 100 and the second light emission spectrum 200. When illumination for a broadcast is considered, this makes it easy to adjust illumination in the site and match colors reproduced by the display. That is, if a color temperature (a track of which is represented by D) of the illumination in the site is generally adjusted by the three primary colors and the color rendering property, which is a reflection characteristic, is secured using complementary spectra among the three primary colors, it is easy to reproduce colors in the site by adjusting, on a monitor side, the balance of the three primary colors to the color temperature in the side, without relying on an intuition and an experience. Therefore, both of the color reproducibility and the color rendering property can be taken into account. The display device is suitable for illumination in the broadcasting site.

If an LED, a full width at half maximum of a light emission spectrum of which is equal to or larger than 10 nm, is used as a solid state light-emitting element, since a missing region of the light emission spectrum can be reduced, it is possible to improve the color rendering property. However, from the viewpoint of the functions and the structure of a lighting device, since a spread angle of emitted light of the LED is wide, efficiency of incidence of excitation light on the wavelength converting section is low. If it is attempted to set the LED and the wavelength converting section close to each other and improve the efficiency of incidence, a temperature rise of the lamp section increases and an optical output decreases.

On the other hand, in the solid state lighting device according to the first embodiment, even if the solid state light-emitting element such as an LD and the lamp section are separated via the light guide section, it is possible to keep the efficiency of incidence on the wavelength converting section high. As a result, it is possible to reduce a temperature rise of the lamp section. Further, the light-emitting element for wavelength complement has the light emission spectrum in a region where visual sensitivity is higher than the light emission spectra of the first and second solid state light-emitting elements 91 and 92. Therefore, it is possible to complement the missing region of the light emission spectrum with lower power consumption and efficiently improve the color rendering property. Further, it is easy to reduce the lamp section in size and weight. A degree of freedom of design of the lighting device is greatly improved.

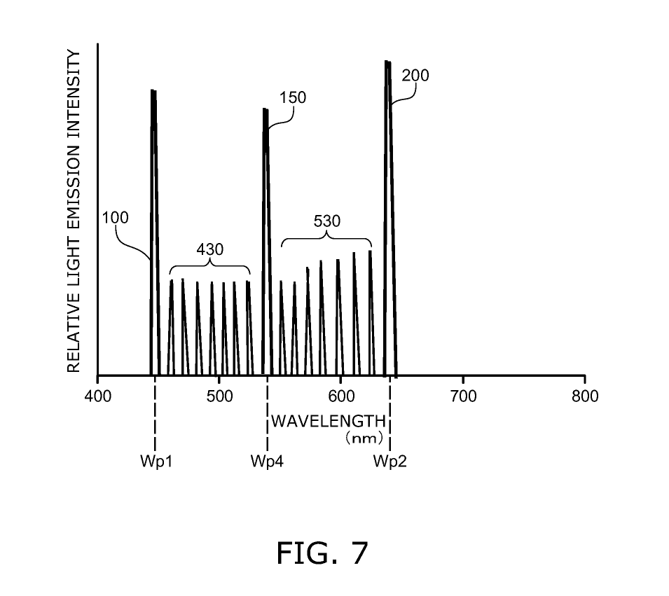

FIG. 7 is a schematic diagram of a light emission spectrum of a solid state lighting device in a second embodiment.

The solid state lighting device in the second embodiment further includes, between the first light emission spectrum 100 and the second light emission spectrum 200, a main light emission spectrum of fourth light from a fourth solid state light-emitting element having a peak wavelength Wp4. The peak wavelength Wp4 of the fourth light is set to a wavelength of a green to yellow color (510 to 570 nm) or the like. The width of a light emission spectrum 150 is smaller than 5 nm. Such a solid state light-emitting element can be an LD of the green color to yellow color, an SHG (Second Harmonic Generation) element, or the like.

A light emission spectrum missing region between the first light emission spectrum 100 and the second light emission spectrum 200 is complemented by a plurality of first light-emitting elements for wavelength complement having a light emission spectrum 430 and a plurality of first light-emitting elements for wavelength complement having a light emission spectrum 530. The plurality of first light-emitting elements for wavelength complement 93 and 94 can be, for example, a plurality of LDs, an interval between adjacent two peak wavelengths of which is equal to or smaller than 5 nm and the width of light emission spectra of which is smaller than 5 nm. In this case, it is more preferable to provide a light scattering layer including a light scattering material in the lamp section to reduce LD light in coherency because safety is improved.

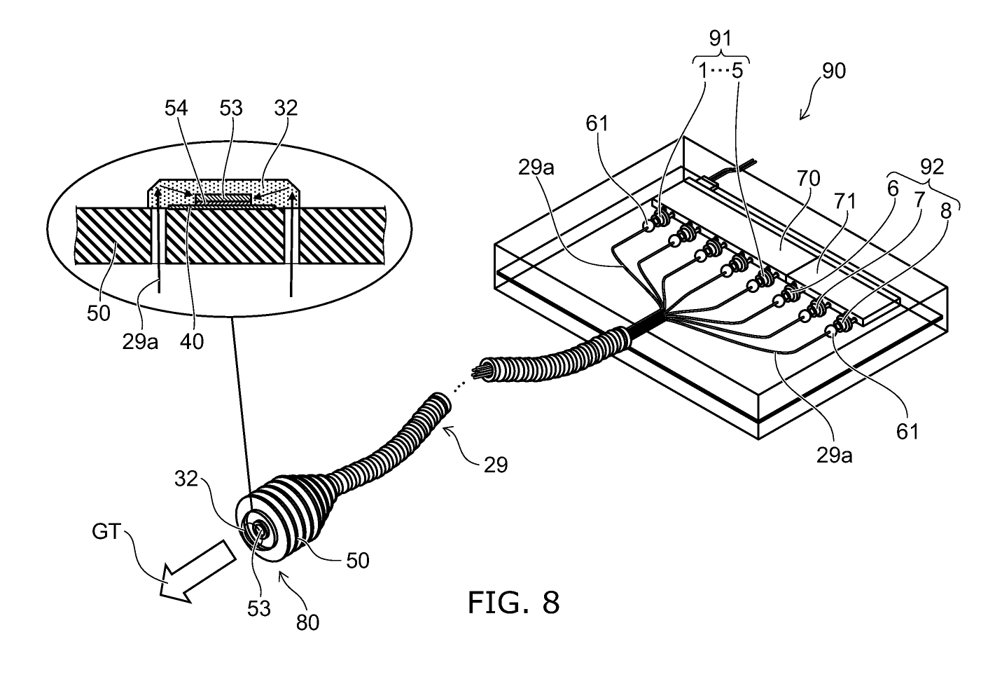

FIG. 8 is a schematic perspective view of a solid state lighting device according to a third embodiment.

The solid state lighting device includes the light source for illumination 90, the light guide section 29, and the lamp section 80. The light source for illumination 90 includes the first solid state light-emitting element 91 and the second solid state light-emitting element 92. The lamp section 80 includes a first wavelength converting section configured to emit first light (provided on, for example, the reflection plate 40 but not shown in the figure).

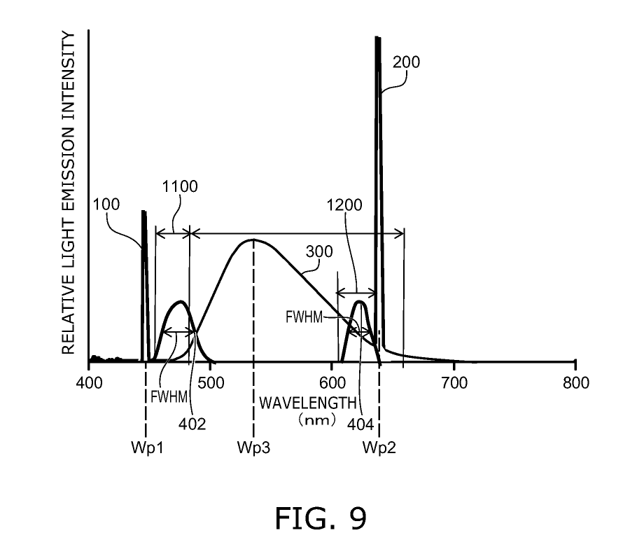

FIG. 9 is a schematic diagram of a light emission spectrum of the solid state lighting device according to the third embodiment.

The first solid state light-emitting element 91 emits first light having the width of the light emission spectrum 100 smaller than 5 nm in a visible light wavelength region. The second solid state light-emitting element 92 emits second light having the width of the light emission spectrum 200 smaller than 5 nm and having the peak wavelength Wp2 larger than the peak wavelength Wp1 of the first light by 5 nm or more in the visible light wavelength region. The first wavelength converting section includes a YAG phosphor or the like, absorbs the first light, and emits first wavelength-converted light having the peak wavelength Wp3 larger than the peak wavelength Wp1 of the first light and smaller than the peak wavelength Wp2 of the second light and having the wide light emission spectrum 300.

A second light-emitting element for wavelength complement includes, as a third wavelength converting section, for example, a semiconductor laminated body including an active layer of a blue LED or a semiconductor laminated body including an active layer of a red LED. If a semiconductor laminated body 53 is undoped, the efficiency of photoluminescence (PL) can be increased. That is, it is unnecessary to feed an electric current to the semiconductor laminated body 53. If an active layer 53a of the semiconductor laminated body 53 is formed in an MQW (Multi Quantum Well) structure, it is easy to design the semiconductor laminated body 53 in a PL spectral shape effective for improvement of a color rendering property.

As shown in FIG. 9, if blue excitation light is irradiated on the MQW active layer 53a of the semiconductor laminated body 53 made of undoped InGaN, third light, which is PL emitted light, is generated at high efficiency. If blue excitation light is irradiated on the MQW active layer 53a of the semiconductor laminated body 53 made of undoped AlInGaP, the third light is generated at high efficiency. A PL light emission spectrum 404 does not sweep to an infrared region and can properly complement the bottom region 1200 and improve the color rendering property of a red region. A PL light emission spectrum 402 can properly complement the missing region 1100 and improve the color rendering property of a blue region. In the light emission intensity of the continuous PL light emission spectra 402 and 404, a full width at half maximum FWHM, which is the width of a wavelength at which light emission intensity is a half of a peak value, is equal to or larger than 5 nm.

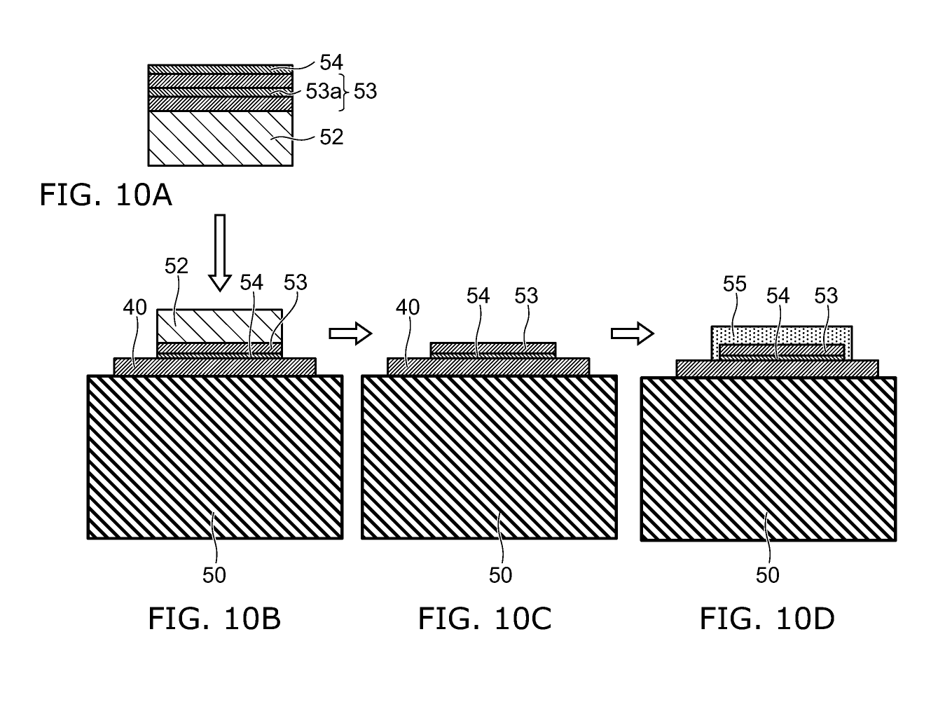

FIGS. 10A to 10D are schematic diagrams for explaining a method for manufacturing a second light-emitting element for wavelength complement. That is, FIG. 10A is a schematic sectional view of a chip, FIG. 10B is a schematic sectional view of a state in which the chip is bonded to a reflection plate, FIG. 10C is a schematic sectional view after selective etching, and FIG. 10D is a schematic sectional view in which a wavelength converting section is provided.

FIG. 10A is a schematic sectional view of the third wavelength converting section in which the semiconductor laminated body 53 including the MQW active layer 53a is provided on a GaAs substrate 52. A reflection layer 54 is provided on the surface of the semiconductor laminated body 53. As shown in FIG. 10B, the reflection plate 40 is provided on the supporting body 50 and the reflection plate 40 and the reflection layer 54 are bonded. Further, as shown in FIG. 10C, the GaAs substrate 52 is removed. Subsequently, as shown in FIG. 10D, the active layer 53a can be coated with a YAG phosphor 55.

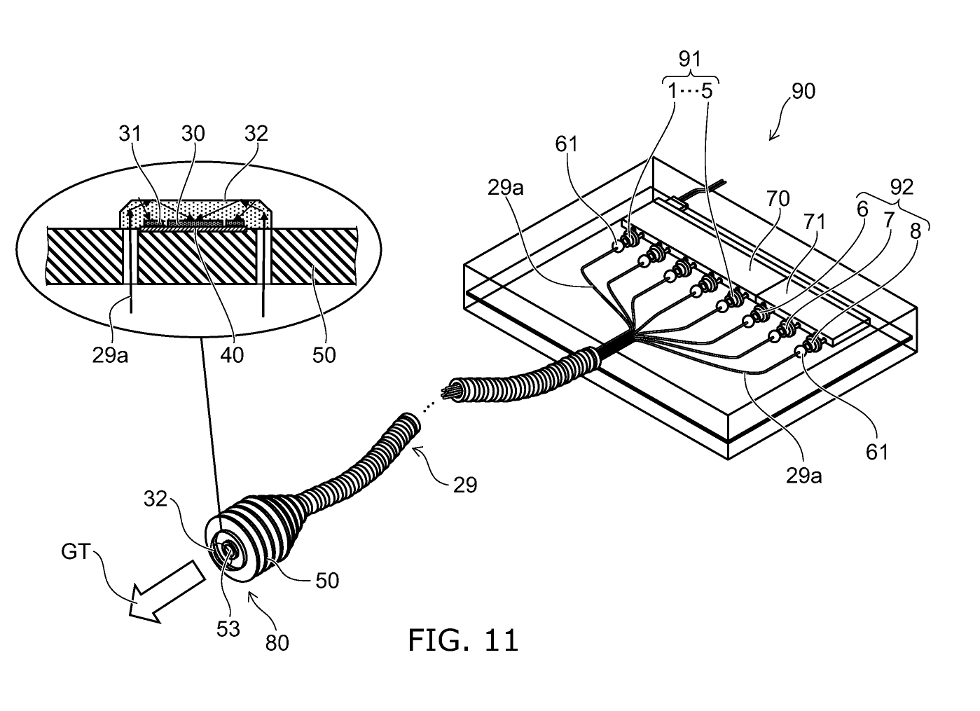

FIG. 11 is a schematic perspective view of a solid state lighting device according to a fourth embodiment.

The solid state lighting device includes the light source for illumination 90, the light guide section 29, and the lamp section 80. The light source for illumination 90 includes the first solid state light-emitting element 91 and the second solid state light-emitting element 92. The first solid state light-emitting element 91 emits first light having the width of the first light emission spectrum 100 smaller than 5 nm in a visible light wavelength region. The second solid state light-emitting element 92 emits second light having the width of the second light emission spectrum 200 smaller than 5 nm and having the peak wavelength Wp2 larger than the peak wavelength Wp1 of the first light by 5 nm or more in the visible light wavelength region.

The lamp section 80 includes, for example, the supporting body 50, the first wavelength converting section 30, and the direction-converting optical section 32. The first wavelength converting section 30 is provided on the supporting body 50, absorbs the first light, and emits first wavelength-converted light. A second wavelength converting section 31 is provided on the supporting body 50, absorbs the first light, and emits second wavelength-converted light. That is, the second wavelength converting section 31 includes a phosphor or the like and acts as a second light-emitting element for wavelength complement. The first and second lights emitted from the light guide section 29 are led into the direction-converting optical section 32. The direction-converting optical section 32 changes traveling directions of the first and second lights and scatters the first and second lights. Scattered lights of the first and second lights and the first and second wavelength-converted lights are emitted from the direction-converting optical section 70. The lamp section 80 only has to be a component including the first wavelength converting section 30 on which at least the first light guided by the light guide section 29 is irradiated. The lamp section 80 is not specifically limited to a light-emitting structure.

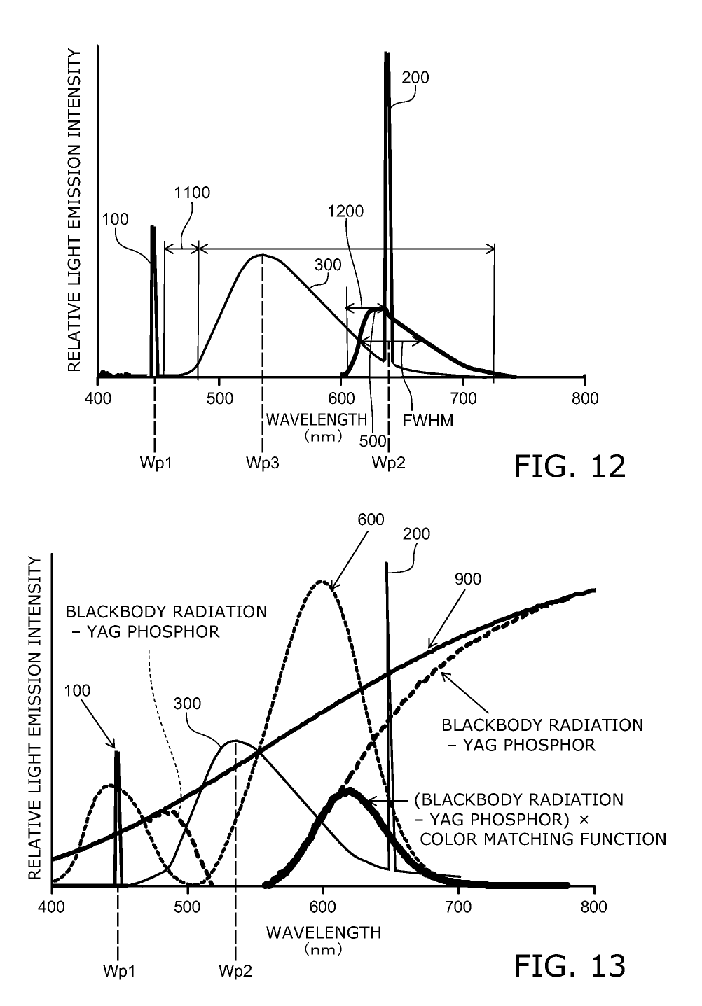

FIG. 12 is a schematic diagram of a light emission spectrum of the solid state lighting device according to the fourth embodiment.

If it is desired to set a color temperature as low as about 3000 K, the light emission intensity of the light emission spectrum 200 of the red LD, which is the second solid state light-emitting element 92, is increased to lower the color temperature.

On the other hand, to improve a color rendering property, the bottom region 1200 of a light emission spectrum is complemented using red wavelength-converted light having the continuous light emission spectrum 500. For example, in a region equal to or smaller than the peak wavelength Wp2 of the second light, second wavelength-converted light having the continuous light emission spectrum 500, the full width at half maximum FWHM of which is equal to or larger than 5 nm, is generated to complement a red region. In this case, the intensity of the light emission spectrum 500 may be relatively low. Therefore, even if a red phosphor having low efficiency is used, a fall in overall efficiency is small.

FIG. 13 is a schematic diagram of a light emission spectrum of a solid state lighting device according to a fifth embodiment.

If a light emission spectrum of the second wavelength converting section including the phosphor or the like substantially coincides with a light emission spectrum obtained by multiplying a light emission spectrum 900 of blackbody radiation with a color matching function 600, the light emission spectrum can be complemented. However, the shapes of the light emission spectra sometimes do not coincide with each other. FIG. 13 shows a method of determining a light emission spectrum shape for improving the bottom region 1200 when the light emission spectra do not coincide with each other.

A color rendering property can be maximized if a light emission spectrum coinciding with the blackbody radiation spectrum 900 at a color temperature of the lamp section 80 is realized. In the first to fourth embodiments, the visual sensitivity of the first light emission spectrum 100 of the first solid state light-emitting element 91 and the visual sensitivity of the second light emission spectrum 200 of the second solid state light-emitting element 92 are lower than the visual sensitivity of a light emission spectrum region between the first light emission spectrum 100 and the second light emission spectrum 200. Therefore, the improvement of the color rendering property is easier if the color rendering property is optimized in a region where visual sensitivity is relatively high.

The blackbody spectrum 900 having a color temperature of 3000 K increases according to a wavelength. On the other hand, the light emission spectrum 300 of a YAG green phosphor has a peak value of light emission intensity at about 520 nm. A color matching function of a red region is as shown in FIG. 13. An optimum light emission spectrum for wavelength complement can be represented by (blackbody radiation spectrum 900-wavelength converted-light emission spectrum 300)×color matching function. Consequently, it is easy to set the average color rendering index Ra as high as, for example, 85 or more. That is, if the width of a light emission spectrum is large like the width of the continuous light emission spectrum 300 of wavelength-converted light, it is preferable to determine a light emission spectrum shape as shown in FIG. 13.

The shape of a light emission spectrum is different according to which of the color rendering property and the efficiency is prioritized. If the efficiency is prioritized, the light emission spectrum shown in FIG. 9 small on a long wavelength side where the visual sensitivity is low is optimum.

The same idea can be applied when a color temperature is high and the missing region 1100 of a blue region is desired to be complemented. When the color temperature changes, a blackbody radiation spectrum also changes. Therefore, it is possible to control the shape of a light emission spectrum for complement according to the change in the black radiation spectrum and dynamically realize high color rendering property.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solid state lighting device comprising:
a first solid state light-emitting element configured to emit first light having a first light emission spectrum having width smaller than 5 nm in a visible light wavelength region;
a second solid state light-emitting element configured to emit second light having a second light emission spectrum having width smaller than 5 nm and a peak wavelength larger than a peak wavelength of the first light by 5 nm or more in the visible light wavelength region; and
a plurality of first light-emitting elements for wavelength complement configured to respectively emit lights having light emission spectra having width smaller than 5 nm,
a third light including a set of the lights from the plurality of first light-emitting elements for complement, and
a third light emission spectrum of the third light complementing a region between the first light emission spectrum and the second light emission spectrum.

2. The device according to claim 1, wherein the third light includes at least a pair of lights having a peak wavelength interval equal to or smaller than 5 nm.

3. The device according to claim 1, wherein the first and second solid state light-emitting elements and the plurality of first light-emitting elements for wavelength complement are semiconductor lasers.

4. The device according to claim 1, further comprising:
a light guide section configured to guide the first light, the second light, and the third light; and
a lamp section including a first wavelength converting section configured to absorb at least the first light guided by the light guide section, emit first wavelength-converted light having a peak wavelength larger than the peak wavelength of the first light and smaller than the peak wavelength of the second light, and scatter the first, second, and third lights,
scattered lights of the first, second, and third lights and the first wavelength-converted light being emitted from the lamp section.

5. The device according to claim 4, wherein the third light emission spectrum substantially coincides with a shape obtained by multiplying, with a color matching function, a value obtained by subtracting the light emission spectrum of the first wavelength-converted light from a blackbody radiation spectrum at a requested color temperature and complements a region between the first light emission spectrum and the second light emission spectrum.

6. The device according to claim 1, further comprising:
a third solid state light-emitting element configured to emit fourth light having width of a light emission spectrum smaller than 5 nm and having a peak wavelength larger than the peak wavelength of the first light by 5 nm or more and smaller than the peak wavelength of the second light by 5 nm or more in the visible light wavelength region, the third solid state light-emitting element including a semiconductor laser.

7. The device according to claim 6, wherein the third light emission spectrum substantially coincides with a shape obtained by multiplying a blackbody radiation spectrum at a requested color temperature with a color matching function.

8. A solid state lighting device comprising:
a first solid state light-emitting element configured to emit first light having a first light emission spectrum having width smaller than 5 nm in a visible light wavelength region;
a second solid state light-emitting element configured to emit second light having a second light emission spectrum having width smaller than 5 nm and a peak wavelength larger than a peak wavelength of the first light by 5 nm or more in the visible light wavelength region; and
a second light-emitting element for wavelength complement configured to emit third light having a continuous third light emission spectrum having a full width at half maximum equal to or larger than 5 nm in the visible light wavelength region and for complementing a region between the first light emission spectrum and the second light emission spectrum, the second light-emitting element for wavelength complement including a second wavelength converting section configured to absorb the first light and emit second wavelength-converted light having a peak wavelength larger than the peak wavelength of the first light or a third wavelength converting section configured to set at least one of the first light and the second light as excitation light and emit third wavelength-converted light having a peak wavelength larger than a peak wavelength of the excitation light.

9. The device according to claim 8, wherein the second wavelength converting section includes a phosphor.

10. The device according to claim 8, wherein the third wavelength converting section includes a semiconductor laminated body configured to perform photoluminescence light emission.

11. The device according to claim 10, wherein the semiconductor laminated body includes an active layer and layers on both sides that sandwich the active layer, the semiconductor laminated body being an undoped layer.

12. The device according to claim 8, further comprising:
a light guide section configured to guide the first and second lights; and
a lamp section including a first wavelength converting section configured to absorb the first light guided by the light guide section, emit first wavelength-converted light having a peak wavelength larger than the peak wavelength of the first light and smaller than the peak wavelength of the second light, and scatter the first and second lights,
scattered lights of the first and second lights, the first wavelength-converted light, and the third light being emitted from the lamp section.

13. The device according to claim 12, wherein
the second light-emitting element for wavelength complement is provided on a supporting section,
the third light emission spectrum substantially coincides with a shape obtained by multiplying, with a color matching function, a value obtained by subtracting the light emission spectrum of the first wavelength-converted light from a blackbody radiation spectrum at a requested color temperature, and
the scattered lights of the first and second lights, the first wavelength-converted light, and the third light are mixed and emitted from the lamp section.

14. The device according to claim 8, further comprising:
a third solid state light-emitting element having width of a light emission spectrum smaller than 5 nm and having a peak wavelength larger than the peak wavelength of the first light by 5 nm or more and smaller than the peak wavelength of the second light by 5 nm or more in the visible light wavelength region.

15. The device according to claim 14, wherein the third light emission spectrum of the second light-emitting element for wavelength complement substantially coincides with a shape obtained by multiplying a blackbody radiation spectrum at a requested color temperature with a color matching function and complements a region between the first light emission spectrum and the second light emission spectrum.

16. The device according to claim 1, wherein
the peak wavelength of the first light is equal to or larger than 420 nm and equal to or smaller than 480 nm,
the peak wavelength of the second light is equal to or larger than 620 nm and equal to or smaller than 650 nm, and
the peak wavelength of the third light is equal to or larger than 460 nm and equal to or smaller than 630 nm.

17. The device according to claim 8, wherein
the peak wavelength of the first light is equal to or larger than 420 nm and equal to or smaller than 480 nm,
the peak wavelength of the second light is equal to or larger than 620 nm and equal to or smaller than 650 nm, and
the peak wavelength of the third light is equal to or larger than 460 nm and equal to or smaller than 630 nm.
